(19) United States
(12) Patent Application Publication
(10) Pub. No.: US 2009/0155984 A1
(43) Pub. Date: Jun. 18, 2009

(54) Backside protection film, method of forming the same and method of manufacturing a semiconductor package using the same

(76) Inventors: Won-keun Kim, Hwaseong-si (KR); Yong-kwan Lee, Yongin-si (KR)

Correspondence Address: LEE & MORSE, P.C., 3141 FAIRVIEW PARK DRIVE, SUITE 500, FALLS CHURCH, VA, 22042, US

(21) Appl. No.: 12/314,361

(22) Filed: Dec. 9, 2008

(30) Foreign Application Priority Data
Dec. 12, 2007 (KR) 10-2007-0129055

(51) Int. Cl. H01L 21/77; H01L 21/00

(52) U.S. Cl. 438/463; 438/465; 257/E21.598

(57) ABSTRACT

A method of forming a backside protection film includes forming a first coating layer on a first heterogeneous film, the first coating layer being at a C-stage state, forming a second coating layer on a second heterogeneous film, the second coating layer being at a B-stage state, separating the first coating layer from the first heterogeneous film, and attaching the first coating layer to the second coating layer, the second coating layer being between the second heterogeneous film and the first coating layer, and each of the first and second heterogeneous films being formed by coating a first material layer with a second material.

### BACKGROUND OF THE INVENTION

1. Field of the Invention

Example embodiments relate to a backside protection film used for manufacturing a semiconductor package, to a method of forming the same, and to a method of manufacturing a semiconductor package using the same. More particularly, example embodiments relate to a backside protection film used for manufacturing a wafer level package, to a method of forming the same, and to a method of manufacturing a wafer level package using the same.

2. Description of the Related Art

As electronic appliances become small-sized and lightweight in response to the development of semiconductor industries and users' needs, semiconductor devices, which may be components of electronic appliances, may also decrease in size and weight. Therefore, in order to minimize a size of a semiconductor device, e.g., a semiconductor package, a wafer level -package with a wafer chip size may be used.

Manufacturing of the semiconductor package may require a dicing process, i.e., a process of cutting a wafer into separate pieces having semiconductor chips thereon. A film may be used to maintain the wafer stationary during the dicing process, followed by removal of the film after forming semiconductor chips in the dicing process. Portions of the conventional film, however, may remain on the semiconductor chips, thereby damaging the semiconductor chips or contaminating the semiconductor chips.

The wafer level package may require encapsulation for protection against external impacts. Since the wafer level package may include an electrical connecting portion, e.g., bumps, balls, or the like, on the wafer between interconnection lines and an external apparatus, the conventional wafer level package may require a very complicated encapsulation process to provide sufficient external exposure to the electrical connecting portion of the chip. Further, cracks may be generated in the semiconductor chip during dicing, thereby decreasing reliability of the semiconductor device.

### SUMMARY OF THE INVENTION

Example embodiments are therefore directed to a backside protection film used for manufacturing a semiconductor package, to a method of forming the same, and to a method of manufacturing a semiconductor package using the same, which substantially overcome one or more of the disadvantages of the related art.

It is therefore a feature of an example embodiment to provide a method of manufacturing a backside protection film capable of easily encapsulating a semiconductor package without damage to the semiconductor chip.

It is another feature of an example embodiment to provide a method of manufacturing a semiconductor package using a backside protection film capable of easy encapsulation so that damage does not occur to the semiconductor chip during dicing.

At least one of the above and other features and advantages of the present invention may be realized by providing a method of forming a backside protection film, including forming a first coating layer on a first heterogeneous film, the first coating layer being at a C-stage state, forming a second coating layer on a second heterogeneous film, the second coating layer being at a B-stage state, separating the first coating layer from the first heterogeneous film, and attaching the first coating layer to the second coating layer, the second coating layer being between the second heterogeneous film and the first coating layer, and each of the first and second heterogeneous films being formed by coating a first material layer with a second material.

The first coating layer may be formed of a substantially same material as the second coating layer. Each of the first and second coating layers may include one or more of a silicone resin, an epoxy resin, a polyimide resin, or an acryl based resin. Forming each of the first and second coating layers may include heat treatment of respective first and second coating materials on respective first and second heterogeneous films, such that the first and second coating materials may be transformed into layers at a C-stage state and a B-stage state, respectively.

At least one of the above and other features and advantages of the present invention may be realized by providing a method of manufacturing a semiconductor package, including forming a first coating layer on a first heterogeneous film, the first coating layer being at a C-stage state, forming a second coating layer on a second heterogeneous film, the second coating layer being at a B-stage state, and each of the first and second heterogeneous films being formed by coating a first material layer with a second material, separating the first coating layer from the first heterogeneous film, attaching the first coating layer to a first surface of the second coating layer to form a backside protection film, the second coating layer being between the second heterogeneous film and the first coating layer, disposing an annular supporter and a semiconductor wafer on a second surface of the second coating layer, the first and second surfaces of the second coating layer being opposite each other, and the semiconductor wafer being positioned inside the annular supporter, dividing the semiconductor wafer into a plurality of discrete semiconductor chips, such that a space may be formed between adjacent semiconductor chips, forming a protective material layer in the space between the adjacent semiconductor chips, and cutting the protective material layer and the backside protection film to form separate semiconductor packages, each semiconductor package including at least one semiconductor chip.

The method may further include, after dividing the semiconductor wafer into a plurality of discrete semiconductor chips, completely curing the second coating layer of the backside protection film. Completely curing the second coating layer may include heating and/using ultraviolet (UV) irradiation. Dividing the semiconductor wafer into a plurality of discrete semiconductor chips may include, before attaching the annular supporter and the semiconductor wafer on the second coating layer, partially cutting the semiconductor wafer along a scribe lane to form scores in the semiconductor wafer, and extending the backside protection film to divide the semiconductor wafer into the semiconductor chips via the scores. Partially cutting the semiconductor wafer may include using a laser saw, a laser stealth saw, and/or a blade saw. Dividing the semiconductor wafer into a plurality of discrete semiconductor chips may include completely cutting the semiconductor wafer along a scribe lane to form separate portions of the semiconductor wafer, and extending the backside protection film, such that spaces may be formed between the separate portions of the semiconductor wafer, to form discrete semiconductor chips. Completely cutting the semiconductor wafer may include using at least one of a laser saw or a blade saw. Dividing the semiconductor wafer into a plurality of discrete semiconductor chips may further include removing a portion of the second coating layer in the space between the adjacent semiconductor chips.

Forming the protective material layer may include injecting a protective material into the space between the adjacent semiconductor chips, and curing the protective material. Injecting the protective material may include dispensing, screen printing, and/or spin coating. Curing the protective material may include heating and/or UV irradiation of the protective material. Forming the protective material layer may include injecting the protective material into the space between the adjacent semiconductor chips, such that the space may be completely filled with the protective material, the protective material completely overlapping at least two sides of each semiconductor chip. Forming the protective material layer may further include forming the protective material layer on an edge portion of a top surface of each semiconductor chip. Forming the protective material layer may further include forming the protective material layer on an entire top surface of each semiconductor chip, a connection portion on the top surface of the semiconductor chip being exposed for an electrical connection with an external source. Forming the protective material layer may include encapsulating at least three sides of each semiconductor chip by the protective layer and the second coating layer of the backside protection film. Forming each semiconductor package may include encapsulating at least three sides of each semiconductor chip by the protective layer and the backside protection film, the backside protection film including two coating layers cured into a single layer.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a plan view of a backside protection film according to an example embodiment;

FIG. 2 illustrates a cross-sectional view along line II-II′ of FIG. 1;

FIG. 3 illustrates a plan view of a backside protection film according to another example embodiment;

FIG. 4 illustrates a cross-sectional view along line IV-IV′ of FIG. 3;

FIGS. 5-7 illustrate schematic diagrams of sequential stages in a method of forming a backside protection film according to an example embodiment;

FIG. 8 illustrates a view of a backside protection film used in manufacturing of a semiconductor package according to an example embodiment;

FIG. 9 illustrates a cross-sectional view of an annular supporter and a semiconductor wafer on the backside protection film of FIG. 8;

FIG. 10 illustrates a cross-sectional view of a method of separating semiconductor chips according to an example embodiment;

FIGS. 11A-11B illustrate cross-sectional views of methods of forming physical scores in a semiconductor wafer;

FIGS. 12A-12B illustrate cross-sectional views of methods of dividing a semiconductor wafer into semiconductor chips according to example embodiments;

FIGS. 13-14 illustrate cross-sectional views of methods of dividing a semiconductor wafer into semiconductor chips according to other example embodiments; and

FIGS. 15A-15D illustrate cross-sectional views of methods of encapsulating semiconductor packages according to example embodiments;

FIGS. 16A-16D illustrate cross-sectional views of methods of encapsulating semiconductor packages according to other example embodiments; and

FIGS. 17A-17D illustrate cross-sectional views of methods of encapsulating semiconductor packages according to other example embodiments.

### DETAILED DESCRIPTION OF THE INVENTION

Korean Patent Application No. 10-2007-0129055, filed on Dec. 12, 2007, in the Korean Intellectual Property Office, and entitled: “Backside Protection Film, Method of Forming the Same and Method of Manufacturing Semiconductor Package Using the Same,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

As used herein, the expressions “at least one,” “one or more,” and “and/or” are open-ended expressions that are both conjunctive and disjunctive in operation. For example, each of the expressions “at least one of A, B, and C,” “at least one of A, B, or C,” “one or more of A, B, and C,” “one or more of A, B, or C” and “A, B, and/or C” includes the following meanings: A alone; B alone; C alone; both A and B together; both A and C together; both B and C together; and all three of A, B, and C together. Further, these expressions are open-ended, unless expressly designated to the contrary by their combination with the term “consisting of.” For example, the expression “at least one of A, B, and C” may also include an nth member, where n is greater than 3, whereas the expression “at least one selected from the group consisting of A, B, and C” does not.

As used herein, the singular forms “a,” “an” and “the” are intended to include the plural forms as well, unless the context clearly indicates otherwise.

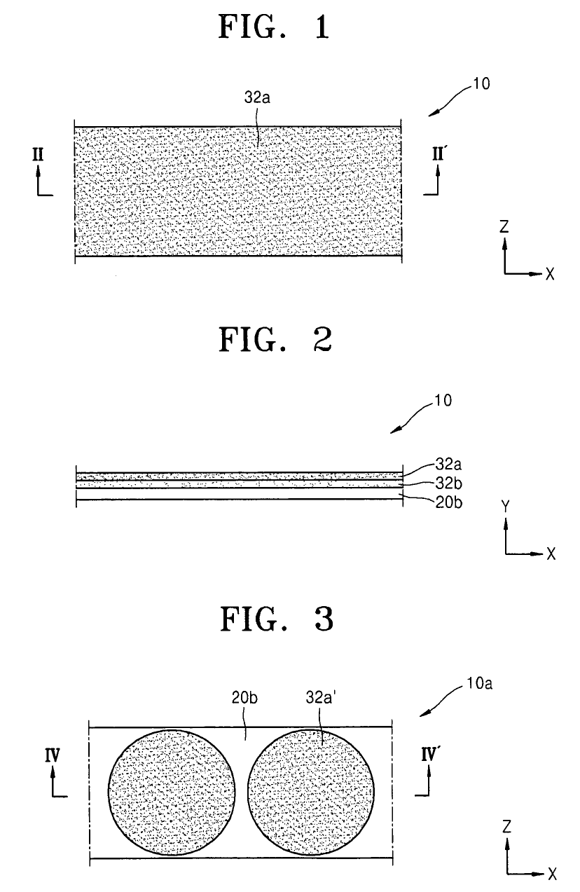

FIG. 1 illustrates a plan view of a backside protection film 10 according to an example embodiment, and FIG. 2 illustrates a cross-sectional view along line II-II′ of FIG. 1.

Referring to FIGS. 1-2, the backside protection film 10 may include first and second coating layers 32a and 32b on a heterogeneous film 20b. The second coating layer 32b and the first coating layer 32a may be sequentially formed on the heterogeneous film 20b, as illustrated in FIG. 1, so the second coating layer 32b may be on the heterogeneous film 20b, e.g., the second coating layer 32b may be directly on the heterogeneous film 20b.

The heterogeneous film 20b may be attached on the second coating layer 32b, and may be easily separated from the second coating layer 32b. The heterogeneous film 20b may be a multi-layer film, e.g., the heterogeneous film 20b may include a first material film coated with a second material. For example, the heterogeneous film 20b may be formed by coating a polyethylene based film, e.g., PET and/or PEN, or a polyolefin based film with silicone or a fluorine-base polymer, e.g., Teflon.

The first and second coating layers 32a and 32b may be formed on the heterogeneous film 20b of any suitable material capable of protecting a surface of a semiconductor chip. For example, the first and second coating layers 32a and 32b may be formed of a thermosetting material, e.g., one or more of silicone based material, epoxy based material, polyimide based material, and an acryl based material. The first and second coating layers 32a and 32b may be formed of materials exhibiting substantially same properties, e.g., the first and second coating layers 32a and 32b may be formed of a substantially same material.

The first coating layer 32a may be at a C-stage state, and the second coating layer 32b may be the B-stage state. In this respect it is noted that “A-stage state” refers to a state of a material, e.g., a thermosetting resin, in which the material may be still soluble in predetermined liquids and may be fusible. “B-stage state” refers to a state of a material, e.g., a thermosetting resin, in which the material may swell when in contact with predetermined liquids and may soften when heated, but may not entirely dissolve or fuse in the predetermined liquids, i.e., the material may be deformable, e.g., an adhesive, but curing of the material may not proceed despite removal of a solvent from a corresponding A-stage state material. “C-stage state” refers to a state of a material, e.g., a thermosetting resin, in which the material may be relatively insoluble and infusible, i.e., the material may be at a completely cured state. Therefore, the A-stage state may become the B-stage through a heat treatment, and the C-stage state may be, e.g., a fully cured adhesive layer, resulting in substantially irreversible hardening and insolubility.

For example, the second coating layer 32b at the B-stage state may be an adhesive, and the first coating layer 32a at the C-stage state may be completely cured, i.e., not an adhesive. Therefore, when the second coating layer 32b at the B-stage state is disposed between the heterogeneous film 20b and the first coating layer 32a at the C-stage state, the first coating layer 32a and the heterogeneous film 20b may protect the second coating layer 32b, e.g., an adhesive, therebetween. For example, the first and second coating layers 32a and 32b and the heterogeneous film 20b may have substantially same dimensions along their width/length directions, so the first coating layer 32a and the heterogeneous film 20b may completely overlap, e.g., continuously, respective surfaces of the second coating layer 32b, as illustrated in FIG. 2.

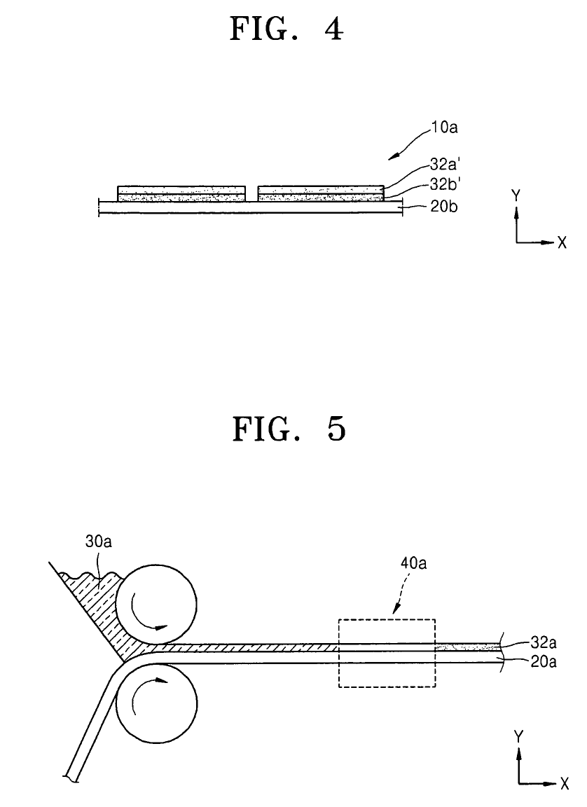

FIG. 3 illustrates a plan view of a backside protection film according to another example embodiment, and FIG. 4 illustrates a cross-sectional view along line IV-IV′ of FIG. 3. Referring to FIGS. 3 and 4, a backside protection film 10a may include a second coating layer 32b′ and a first coating layer 32a′ on the heterogeneous film 20a. The first and second coating layers 32a′ and 32b′ may be substantially the same as the first and second coating layers 32a and 32b, respectively, of the backside protection film 10 described previously with reference to FIGS. 1-2, with the exception of having a circular shape.

That is, the first and second coating layers 32a′ and 32b′ may have circular cross-sections in a plane parallel to a plane of the heterogeneous film 20b, i.e., in the xz-plane, as illustrated in FIG. 3. For example, portions of the first and second coating layers 32a and 32b in FIGS. 1 and 2 may be removed from the heterogeneous film 20b, with the exception of the circular shapes illustrated in FIG. 3, to form the first and second coating layers 32a′ and 32b′. For example, each of the first and second coating layers 32a′ and 32b′ may include a plurality of circular shapes spaced apart from each other, as illustrated in FIGS. 3-4. The first and second coating layers 32a′ and 32b′ may overlap each other, e.g., first and second coating layers 32a′ and 32b′ may completely overlap each other. Adjacent circular structures of sequentially formed first and second coating layers 32a′ and 32b′ may be spaced apart from each other to expose a surface of the heterogeneous film 20b therebetween, e.g., each of first and second coating layers 32a′ and 32b′ may include discrete circular portions spaced apart from each other.

The backside protection films 10 and 10a described previously with reference to FIGS. 1-2 and 3-4, respectively, may be attached to a semiconductor wafer including a plurality of semiconductor chips, on which a semiconductor device is formed. For example, if the backside protection 10a is used, the first and second coating layers 32a′ and 32b′ may have a circular shape substantially similar to a shape of the semiconductor wafer. The first and second coating layers 32a′ and 32b′ may be larger than the corresponding semiconductor wafer thereon, i.e., may have a larger diameter, in order to provide sufficient space for attaching a supporter, as will be described below.

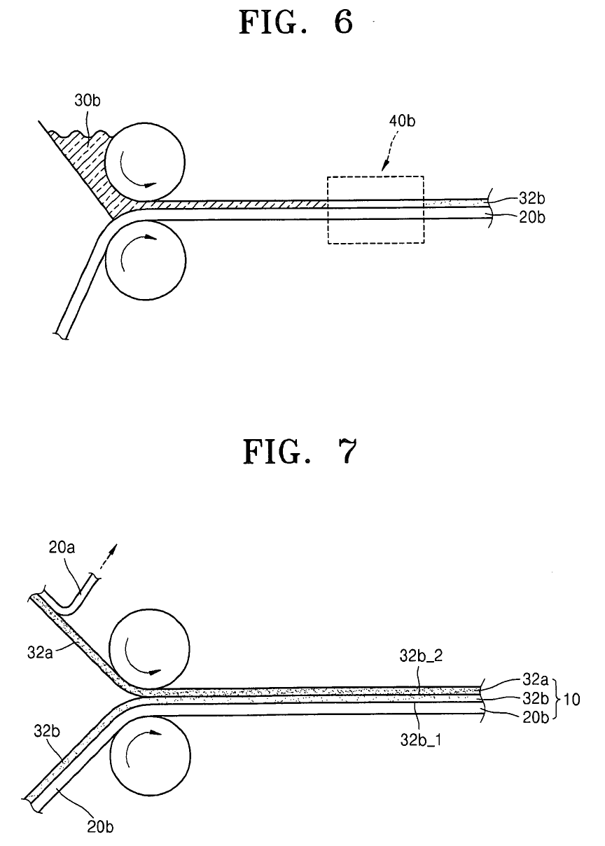

FIGS. 5-7 illustrate sequential stages in a method of manufacturing the backside protection film 10 according to an example embodiment. FIG. 5 illustrates a schematic view of a method of forming the first coating layer 32a according to an example embodiment. FIG. 6 illustrates a schematic view of a method of forming the second coating layer 32b according to an example embodiment. FIG. 7 illustrates a schematic view of a method of forming the backside protection film 10 according to an example embodiment.

Referring to FIG. 5, a supplementary heterogeneous film 20a may be coated with a first coating material 30a. The first coating material 30a may be at an A-stage state, and may include, e.g., one or more of a silicone resin, an epoxy resin, a polyimide resin, and an acryl based resin. The first coating material 30a may be applied to a surface of a supplementary heterogeneous film 20a, e.g., the first coating material 30a may coat an entire surface of the supplementary heterogeneous film 20a. The supplementary heterogeneous film 20a may be formed by coating the first material film with a second material. For example, the supplementary heterogeneous film 20a may be formed by coating a polyethylene based film, e.g., PET or PEN, or a polyolefin based film with silicone or Teflon.

Once the first coating material 30a is coated on the supplementary heterogeneous film 20a, a first heat treatment 40a may be applied to the first coating material 30a coated on the supplementary heterogeneous film 20a to substantially completely cure the first coating material 30a, i.e., transform the A-stage state of the first coating material 30a into a C-stage state, to form the first coating layer 32a on the supplementary heterogeneous film 20a. The first heat treatment 40a may include, e.g., heating or UV irradiation. The supplementary heterogeneous film 20a may be formed so it may be easily separated from the first coating layer 32a.

Referring to FIG. 6, the heterogeneous film 20b may be coated with a second coating material 30b. The second coating material 30b may be at an A-stage state, and may be substantially the same material as the first coating material 30a or may have substantially same properties as the first coating material 30a. The heterogeneous film 20b and the supplementary heterogeneous film 20a may be formed of substantially the same materials or may have substantially same properties, e.g., the heterogeneous film 20b may be formed by coating a polyethylene based film, e.g., PET or PEN, or a polyolefin based film with silicone or Teflon.

Once the second coating material 30b is coated on the heterogeneous film 20b, a second heat treatment 40b may be applied to the second coating material 30b coated on the heterogeneous film 20b to partially cure the second coating material 30b, i.e., transform the A-stage state of the second coating material 30a into a B-stage state, to form the second coating layer 32b on the heterogeneous film 20b. The second heat treatment 40b may include, e.g., heating or UV irradiation. The heterogeneous film 20b may be formed such that it may be easily separated from the second coating layer 32b.

It is noted that during formation of the backside protection film 10, the second coating material 30a may be only partially cured, i.e., may be at a B-stage state. The second coating layer 32b may be completely cured, i.e., transformed into a C-stage state, in a subsequent process, i.e., when the backside protection film 10 is used to form a semiconductor package. Once the second coating layer 32b is completely cured, the first coating layer 302a and the second coating layer 32b may function as a single layer at a C-stage state. For this purpose, the second coating material 30b may have substantially the same properties as the first coating material 30a, e.g., the second coating material 30b may be substantially the same material as the first coating material 30a.

Referring to FIG. 7, the first coating layer 32a may be separated from the supplementary heterogeneous film 20a, and may be attached to the second coating layer 32b. In other words, once the first and second coating layers 32a and 32b are formed on the supplementary heterogeneous film 20a and the heterogeneous film 20b, respectively, the first coating layer 32a may be separated from the supplementary heterogeneous film 20a. The first coating layer 32a may be stacked on the second coating layer 32b, so the second coating layer 32b may be between the heterogeneous film 20b and the first coating layer 32a, as illustrated in FIG. 7. For example, the heterogeneous film 20b may be directly on a first surface 32b_1 of the second coating layer 32b, and the first coating layer 32a may be directly on a second surface 32b_2 of the second coating layer 32b, i.e., the first and second surfaces 32b_1 and 32b_2 of the second coating layer 32b may be opposite each other. It is noted that since the second coating layer 32b is at a B-stage state, i.e., the second coating layer 32b may be an adhesive and may not be completely cured, the first and second surfaces 32b_1 and 32b_2 of the second coating layer 32b may be protected by the heterogeneous film 20b and the first coating layer 32a, respectively.

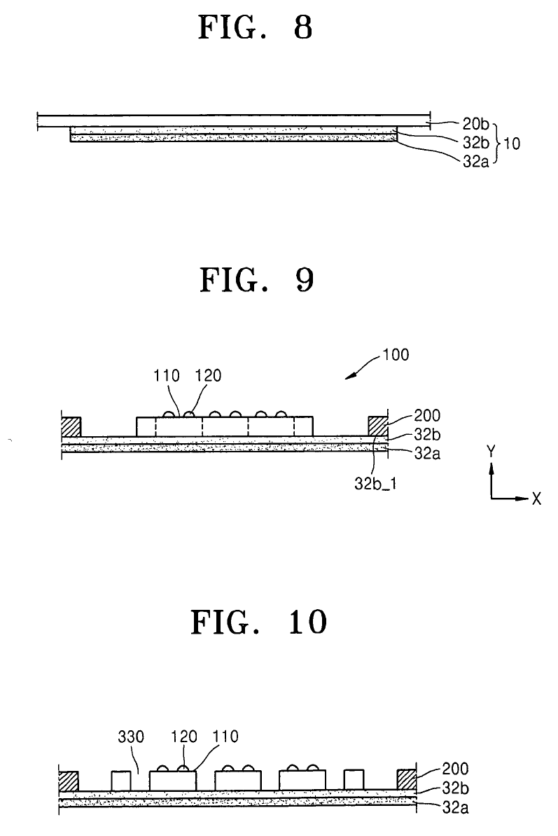

FIGS. 8-17B illustrate cross-sectional views of sequential stages in methods of manufacturing semiconductor packages according to example embodiments.

FIGS. 8-9 illustrate stages in attaching a semiconductor wafer to a backside protection film. FIG. 8 illustrates a cross-sectional view of the backside protection film 10 prepared for manufacturing a semiconductor package according to an example embodiment. FIG. 9 illustrates a cross-sectional view of an annular supporter 200 and a semiconductor wafer 100 attached on the backside protection film 10a.

Referring to FIG. 8, the backside protection film 10 may include the second coating layer 32b between the first coating layer 32a and the heterogeneous film 20b, i.e., a turned over structure of a portion of the backside protection film 10a illustrated in FIGS. 1-2. As discussed previously with reference to FIGS. 1-4, the first coating layer 32a may be at a C stage state, and the second coating layer 32b may be at a B-stage state, so the second coating layer 32b may be an adhesive layer having the heterogeneous film 20b and the first coating layer 32a on the first and second surfaces thereof, respectively.

Referring to FIG. 9, the heterogeneous film 20b may be removed from the backside protection film 10 to expose the first surface 32b_1 of the second coating layer 32b, i.e., a surface facing away from the first coating layer 32a. Next, as illustrated in FIG. 9, the semiconductor wafer 100 and the annular supporter 200 may be disposed on the first surface 32b_1 of the second coating layer 32b. That is, the first coating layer 32a and the second coating layer 32b, from which the heterogeneous film 20b is removed, may be used in a subsequent dicing process.

The annular supporter 200 may have an annular shape with an inner diameter larger than a diameter of the semiconductor wafer 100, so the semiconductor wafer 100 may be positioned on the first surface 32b_1 of the second coating layer 32b inside the annular supporter 200. In other words, the annular supporter 200 may surround the semiconductor wafer 100 along a perimeter of the semiconductor wafer 100. The semiconductor wafer 100 may include a plurality of semiconductor chips 110 and a plurality of connecting portions 120 on each of the semiconductor chips 110. The connecting portions 120 may provide electrical connection with an external apparatus, and may be formed on an upper surface of each semiconductor chip 110. For example, the connecting portions 120 may be bumps or solder balls. A scribe lane, i.e., indicated by perforations in FIG. 9, may be formed between the semiconductor chips 110 of the semiconductor wafer 100.

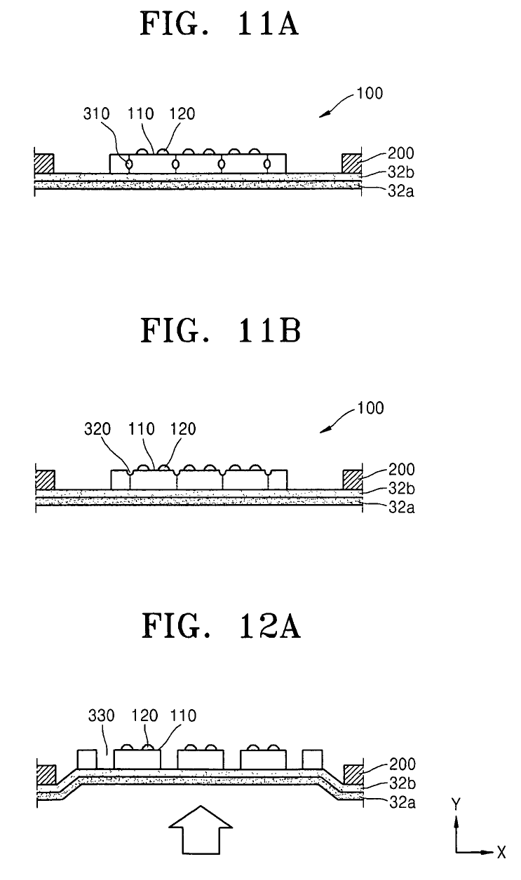

FIGS. 10-12B illustrate stages in a method of separating the semiconductor chips 110. FIG. 10 illustrates an extension of the first and second coating layers 32a and 32b. FIGS. 11A-11B illustrate the formation of physical scores in a semiconductor wafer. FIGS. 12A-12B illustrate methods of dividing the semiconductor wafer 100 into the semiconductor chips 110 according to other example embodiments.

Referring to FIGS. 10-11B, the semiconductor wafer 100 may be treated to separate the semiconductor chips 110 from each other, i.e., to form a space 330 between adjacent semiconductor chips 110. For example, the semiconductor wafer 100 may be scored, i.e., at least partially cut to form notches therein, to form a physical score between adjacent semiconductor chips 110. FIGS. 11A-11B illustrate cross-sectional views of different types of physical scores formed in the semiconductor wafer 100. For example, internal physical scores 310 and/or surface physical scores 320 may be formed in the semiconductor wafer 100, as illustrated in FIGS. 11A-11B.

Referring to FIG. 11A, the internal physical scores 310 may be formed between adjacent semiconductor chips 110 of the semiconductor wafer 100. As illustrated in FIG. 11A, the internal physical cores 310 may be formed inside the semiconductor wafer 100, i.e., formed in an internal portion of the semiconductor wafer 100, between adjacent semiconductor chips 110 using, e.g., a laser. For example, the internal scores 310 may be formed using a laser stealth saw inside the semiconductor wafer 100 under the scribe lane.

Referring to FIG. 11B, the surface physical scores 320 may be formed on an external surface of the semiconductor wafer 100 between adjacent semiconductor chips 110. For example, small scores may be formed on a top surface of the semiconductor wafer 100, e.g., on the scribe lane of the semiconductor wafer 100. The surface scores 320 may be formed using, e.g., a laser saw or a blade saw.

Referring back to FIG. 10, once the semiconductor wafer 100 is scored, the first and second coating layers 32a and 32b may be extended, i.e., stretched along the x-axis, so that the semiconductor wafer 100 may be divided at the scores to form the separated semiconductor chips 110 with the spaces 330 therebetween. For this purpose, the first and second coating layers 32a and 32b may be formed of a material having a good extensibility, and the second coating layer 32b may exhibit good adhesion. The annular supporter 200 may maintain the extended state of the first and second coating layers 32a and 32b.

Next, the first and second coating layers 32a and 32b may be heat treated at their extended state, e.g., via thermal heat or UV irradiation, so the second coating layer 32b may be completely cured, i.e., the second coating layer 32b may transform from a B-stage state to a C-stage state. Accordingly, after completely curing the second coating layer 32b, both the first and second coating layers 32a and 32b may be at a C-stage state, e.g., the first and second coating layers 32a and 32b may function as a single layer coating at a C-stage state.

Alternatively, as illustrated in FIGS. 12A-12B, the first and second coating layers 32a and 32b may be extended to separate the semiconductor chips 110 at the scores formed therebetween by application of force to the semiconductor wafer 100. Since the semiconductor wafer 100 may have a substantially single crystal structure, the semiconductor wafer 100 may be divided at the small scores when a force is applied thereto.

Referring to FIG. 12A, a force, i.e., indicated by an arrow in FIG. 12A, may be applied to the semiconductor wafer 100 via a surface of the first coating layer 32a, i.e., a surface of the first coating layer 32a facing away from the semiconductor wafer 100. Application of the force, i.e., along the y-axis, may extend a portion of the first and second coating layers 32a and 32b along the y-axis, as illustrated in FIG. 12A, thereby forcing division of the semiconductor wafer 100 at the scores to form the semiconductor chips 110 with spaces 330 therebetween.

The force applied to the first coating layer 32a may be, e.g., a support plate pushed up along the y-axis against the first coating layer 32a and having a diameter larger than the diameter of the semiconductor wafer 100 and smaller than the inner diameter of the annular supporter 200. In another example, the force applied to the first coating layer 32a may be applied by contacting the support plate with the surface of the first coating layer 32a and then pushing down along the y-axis the annular supporter 200, i.e., in a direction opposite the direction of the indicated arrow. In response to the applied force, a portion of the first and second coating layers 32a and 32b in an inner side of the annular supporter 200 may be extended to force division of the semiconductor wafer 100 at the scores.

In another example, as illustrated in FIG. 12B, the annular supporter 200 around the semiconductor wafer 100 may be moved or extended in an outward direction relatively to the semiconductor wafer 100, i.e., along a direction indicated by the arrows in FIG. 12B, to extend the first and second coating layers 32a and 32b along the x-axis. The force applied to the annular supporter 200 may be uniformly applied in an outward direction. The applied force to the first and second coating layers 32a and 32b may divide the semiconductor wafer 100 into a plurality of semiconductor chips 110 with spaces 330 therebetween.

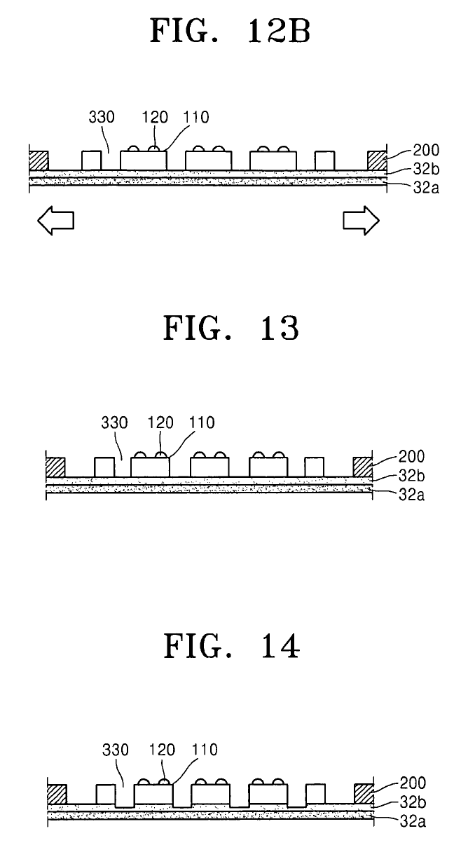

FIGS. 13-14 illustrate a method of dividing the semiconductor wafer 100 into the semiconductor chips 110 according to another example embodiment.

Referring to FIG. 13, the semiconductor wafer 100 may be cut to separate the semiconductor chips 110 and form spaces 330 between adjacent separated semiconductor chips 110. That is, the semiconductor wafer 100 may be completely cut along the scribe lane, e.g., using a laser saw or a blade saw, to expose the first surface 32b-1 of the second coating layer 32b. It is noted that since cutting is used to separate the semiconductor chips 110, physical scores may not be formed on the surface or on the inside of the semiconductor wafer 100. It is further noted that a portion of the second coating layer 32b may also be cut, i.e., removed, during formation of the spaces 330, e.g., a depth of the space 330 along the y-axis may be larger than a height of a semiconductor wafer 100 along the y-axis, as illustrated in FIG. 14.

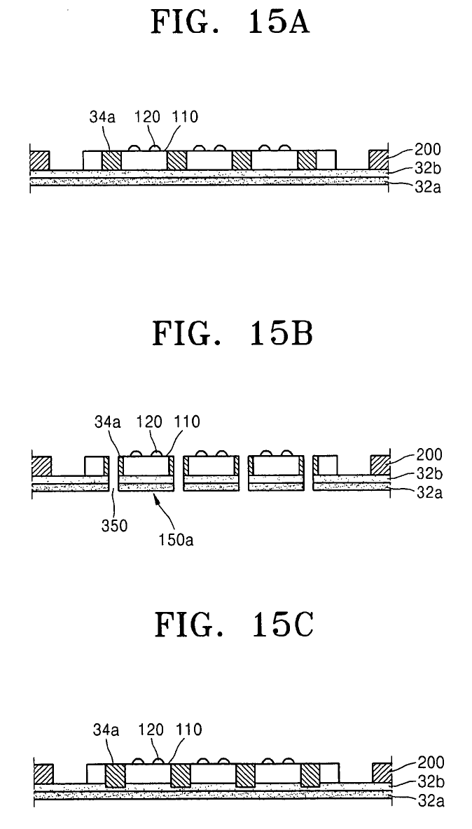

After the semiconductor wafer 100 is treated to separate the semiconductor chips 110 from each other, a protective material may be injected into the spaces 330 between adjacent semiconductor chips 110 to provide encapsulation for each of the semiconductor chips 110. For example, removal of a portion of the second coating layer 32b, as illustrated in FIG. 14, may enlarge the spaces between adjacent semiconductor chips 110, so sufficient space may be provided for injecting the protective material. In another example, extension of the first and second coating layers 32a and 32b, e.g., as illustrated in FIGS. 10-12B, may be adjusted to enlarge the spaces 330 between adjacent semiconductor chips 110 for providing sufficient space for injecting the protective material. A detailed description of encapsulating methods of the semiconductor chips 110 will be described in more detail below with reference to FIGS. 15A-17D.

Referring to FIG. 15A, a protective material 34a may be injected into spaces 330 between adjacent semiconductor chips 110. The protective material 34a may be injected, e.g., through dispensing, screen printing, and/or spin coating. The protective material 34a may be initially a paste, i.e., during injection into the spaces 330, and may be cured, i.e., when disposed in the spaces 330, to protect surfaces of the semiconductor chips 110. For example, as illustrated in FIG. 15A, the protective material 34a may be immediately injected to completely fill the spaces 330, so an upper surface of the protective material 34a may be substantially level with an upper surface of the semiconductor chips 110. As such, the protective material 34a and the second coating layer 32b may encapsulate three sides of each semiconductor chip 110. The protective material 34a may include, e.g., one or more of a silicon resin, an epoxy resin, a polyimide resin, or an acryl based resin. The protective material 34a may be a material having substantially same properties as the first coating material 30a and/or the second coating material 30b. For example, the protective material 34a may include a substantially same material as the first coating material 30a and/or the second coating material 30b.

Referring to FIG. 15B, once the protective material 34a is completely cured in the spaces 330, i.e., once the protective material 34a is at a C-stage state, via, e.g., heating or UV irradiation, portions of the protective material 34a may be removed. In particular, a center portion of the protective material 34a in each space 330 may be removed, e.g., completely cut out, to form a space 350. The space 350 may extend through the protective material 34a and through the first and second coating layers 32a and 32b. As a result, a semiconductor package 150a may be defined between two spaces 350. In other words, each semiconductor package 150a may include a semiconductor chip 110 on a single coating layer, i.e., first and second coating layers 32a and 32b cured into a single layer structure, and may be encapsulated by the protective material 34a. The semiconductor packages 150a may be completely separated from each other by spaces 350. Further, a wafer level package may maintain a size similar to that of the semiconductor chip 110 despite the encapsulation.

It is noted that if the second coating layer 32b is not completely cured during formation of the backside protection film 10a, i.e., is not completely at a C-stage state, the second coating layer 32b may be completely cured to the C-stage state during curing of the protective material 34a. Therefore, the protective material 34a, the first coating layer 32a, and the second coating layer 32b may be completely cured to the C-stage state to protect the semiconductor chips 110. It is further noted that the first and second coating layers 32a and 32b may be used in the dicing process as a single layer with the protective material 34a so as to encapsulate each semiconductor chip 110.

Referring to FIGS. 15C-15D, the protective material 34a may be injected into spaces 330 between adjacent semiconductor chips 110, as described previously with reference to FIGS. 15A-15B. In contrast to FIGS. 15A-15B, however, a portion of the second coating layer 32b in FIGS. 15C-15D may be removed, as described previously with reference to FIG. 14. Accordingly, as illustrated in FIG. 15C, a height of the protective material 34a along the y-axis may be larger than a height of the semiconductor wafer 100 along the y-axis.

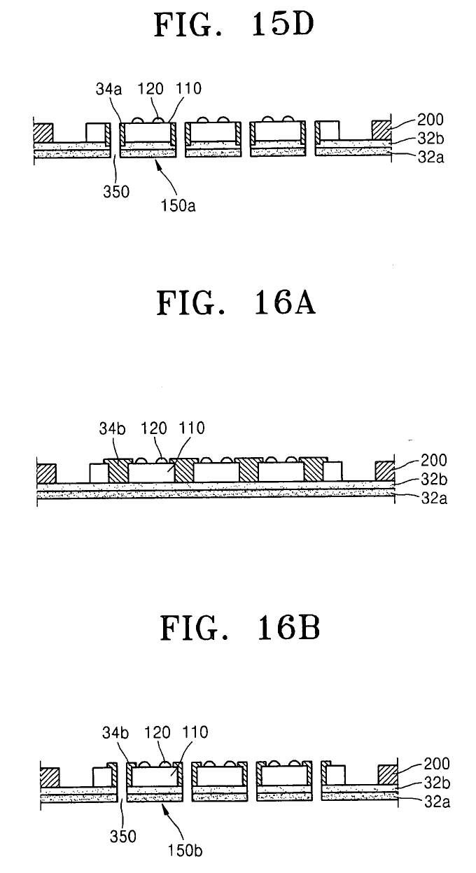

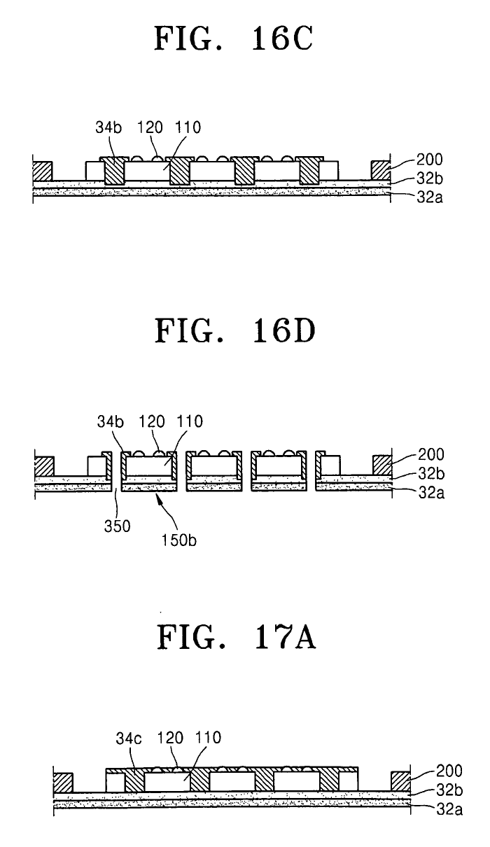

Referring to FIG. 16A, a protective material 34b may be injected into spaces 330 between adjacent semiconductor chips 110, as described previously with reference to FIG. 15A, with the exception of disposing a portion of the protective material 34b on an edge of a top surface of each semiconductor chip 110. In other words, the protective material 34b may completely fill the spaces 330 between adjacent semiconductor chips 110 and may overlap a portion of the top surface of the semiconductor chips 110. Accordingly, three sides of each of the semiconductor chips 110 may be completely encapsulated by the protective material 34b and the second coating layer 32b, and a portion of a fourth side of each semiconductor chip 110 may be at least partially covered by the protective material 34b.

Referring to FIG. 16B, the protective material 34b may be completely cured to the C-stage state through heating or UV irradiation. A center portion of the protective material 34b may be cut, as described previously with reference to FIG. 15B, to form separate semiconductor packages 150b. The first and second coating layers 32a and 32b and the protective material 34b may encapsulate an edge portion of a top surface as well as a bottom surface and side surfaces of each semiconductor chip 110. It is noted that formation of the protective material 34b on the top surface of the semiconductor chip 110 may prevent or substantially minimize damage to the semiconductor chip 110, e.g., an edge of the semiconductor chip 110, due to external impacts.

Referring to FIGS. 16C-16D, the protective material 34b may be injected into spaces 330 between adjacent semiconductor chips 110, as described previously with reference to FIGS. 16A- 16B. In contrast to FIGS. 16A-16B, however, a portion of the second coating layer 32b in FIGS. 16C-16D may be removed, as described previously with reference to FIG. 14. Accordingly, as illustrated in FIG. 16C, a height of the protective material 34b along the y-axis may be larger than a height of the semiconductor wafer 100 along the y-axis.

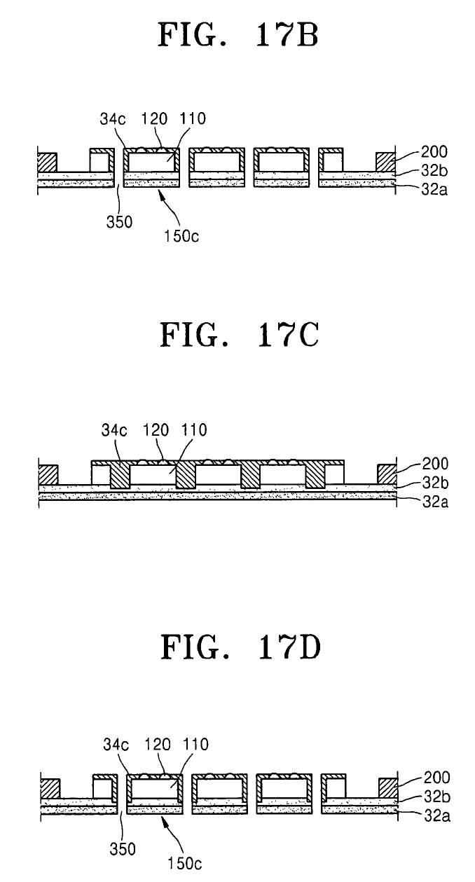

Referring to FIG. 17A, a protective material 34c may be injected into spaces 330 between adjacent semiconductor chips 110, as described previously with reference to FIG. 16A, with the exception of disposing the protective material 34b on an entire top surface of the semiconductor chips 110, i.e., an entire top surface of the semiconductor chips 110 excluding the connecting portion 120 on the top surface of each semiconductor chip 110. Accordingly, the protective material 34b and the second coating layer 32b may substantially encapsulate four sides of each of the semiconductor chips 110, i.e., with the exception of the connecting portions 120.

Referring to FIG. 17B, the protective material 34c may be completely cured to the C-stage state through heating or UV irradiation. A center portion of the protective material 34b may be cut, as described previously with reference to FIG. 16B, to form separate semiconductor packages 150c. The first and second coating layers 32a and 32b and the protective material 34c may encapsulate the top surface as well as the bottom and side surfaces of each semiconductor chip 110.

Referring to FIGS. 17C-17D, the protective material 34c may be injected into spaces 330 between adjacent semiconductor chips 110, as described previously with reference to FIGS. 17A-17B. In contrast to FIGS. 17A-17B, however, a portion of the second coating layer 32b in FIGS. 17C-17D may be removed, as described previously with reference to FIG. 14. Accordingly, as illustrated in FIG. 17C, a height of the protective material 34b along the y-axis may be larger than a height of the semiconductor wafer 100 along the y-axis. As described above, since the protective material 34c and the first and second coating layers 32a and 32b may function as a single layer to encapsulate the semiconductor chip 110, the semiconductor chip 110 may be protected from the outside. Therefore, the semiconductor chip 110 can be protected, e.g., from chemical influence due to the external environment as well as a physical impact.

A backside protection film, a method of forming the same, and a method of manufacturing a semiconductor package using the same according to example embodiments may provide a facilitated dicing process for dividing a wafer into semiconductor chips. The facilitated dicing process may be easily performed in the manufacturing process of the semiconductor package. Also, damage to the semiconductor chips during the dicing process may be minimized.

In addition, the backside protection film may be used as an encapsulating member of the semiconductor package. Therefore, an encapsulating process of the semiconductor package may be simplified, and a removing process of the backside protection film may not be necessary. The entire manufacturing process of the semiconductor package may, therefore, be dimplified. Accordingly, productivity may be improved, and the manufacturing costs may be reduced. Also, damage to the semiconductor chips or contamination, i.e., introduction of foreign substances due to removal of the backside protection film, may not occur. Further, since the encapsulating member may be formed as a single layer, the semiconductor chips of the semiconductor package may provide safer encapsulation and protection from the external environment.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method of forming a backside protection film, comprising:
forming a first coating layer on a first heterogeneous film, the first coating layer being at a C-stage state;
forming a second coating layer on a second heterogeneous film, the second coating layer being at a B-stage state;
separating the first coating layer from the first heterogeneous film; and
attaching the first coating layer to the second coating layer, the second coating layer being between the second heterogeneous film and the first coating layer, and each of the first and second heterogeneous films being formed by coating a first material layer with a second material.

2. The method as claimed in claim 1, wherein the first coating layer is formed of a substantially same material as the second coating layer.

3. The method as claimed in claim 1, wherein each of the first and second coating layers includes one or more of a silicone resin, an epoxy resin, a polyimide resin, or an acryl based resin.

4. The method as claimed in claim 1, wherein forming each of the first and second coating layers includes heat treatment of respective first and second coating materials on respective first and second heterogeneous films, such that the first and second coating materials are transformed into layers at a C-stage state and a B-stage state, respectively.

5. A method of manufacturing a semiconductor package, comprising:
forming a first coating layer on a first heterogeneous film, the first coating layer being at a C-stage state;
forming a second coating layer on a second heterogeneous film, the second coating layer being at a B-stage state, and each of the first and second heterogeneous films being formed by coating a first material layer with a second material;
separating the first coating layer from the first heterogeneous film;
attaching the first coating layer to a first surface of the second coating layer to form a backside protection film, the second coating layer being between the second heterogeneous film and the first coating layer;
disposing an annular supporter and a semiconductor wafer on a second surface of the second coating layer, the first and second surfaces of the second coating layer being opposite each other, and the semiconductor wafer being positioned inside the annular supporter;
dividing the semiconductor wafer into a plurality of discrete semiconductor chips, such that a space is formed between adjacent semiconductor chips;
forming a protective material layer in the space between the adjacent semiconductor chips; and
cutting the protective material layer and the backside protection film to form separate semiconductor packages, each semiconductor package including at least one semiconductor chip.

6. The method as claimed in claim 5, further comprising, after dividing the semiconductor wafer into a plurality of discrete semiconductor chips, completely curing the second coating layer of the backside protection film.

7. The method as claimed in claim 6, wherein completely curing the second coating layer includes heating and/or using ultraviolet (UV) irradiation.

8. The method as claimed in claim 5, wherein dividing the semiconductor wafer into a plurality of discrete semiconductor chips includes:
before attaching the annular supporter and the semiconductor wafer on the second coating layer, partially cutting the semiconductor wafer along a scribe lane to form scores in the semiconductor wafer; and
extending the backside protection film to divide the semiconductor wafer into the semiconductor chips via the scores.

9. The method as claimed in claim 8, wherein partially cutting the semiconductor wafer includes using a laser saw, a laser stealth saw, and/or a blade saw.

10. The method as claimed in claim 5, wherein dividing the semiconductor wafer into a plurality of discrete semiconductor chips includes:
completely cutting the semiconductor wafer along a scribe lane to form separate portions of the semiconductor wafer; and
extending the backside protection film, such that spaces are formed between the separate portions of the semiconductor wafer, to form discrete semiconductor chips.

11. The method as claimed in claim 10, wherein completely cutting the semiconductor wafer includes using at least one of a laser saw or a blade saw.

12. The method as claimed in claim 10, wherein dividing the semiconductor wafer into a plurality of discrete semiconductor chips further comprises removing a portion of the second coating layer in the space between the adjacent semiconductor chips.

13. The method as claimed in claim 5, wherein forming the protective material layer includes:
injecting a protective material into the space between the adjacent semiconductor chips; and
curing the protective material.

14. The method as claimed in claim 13, wherein injecting the protective material includes dispensing, screen printing, and/or spin coating.

15. The method as claimed in claim 13, wherein curing the protective material includes heating and/or UV irradiation of the protective material.

16. The method as claimed in claim 13, wherein forming the protective material layer includes injecting the protective material into the space between the adjacent semiconductor chips, such that the space is completely filled with the protective material, the protective material completely overlapping at least two sides of each semiconductor chip.

17. The method as claimed in claim 16, wherein forming the protective material layer further comprises forming the protective material layer on an edge portion of a top surface of each semiconductor chip.

18. The method as claimed in claim 16, wherein forming the protective material layer further comprises forming the protective material layer on an entire top surface of each semiconductor chip, a connection portion on the top surface of the semiconductor chip being exposed for an electrical connection with an external source.

19. The method as claimed in claim 16, wherein forming the protective material layer includes encapsulating at least three sides of each semiconductor chip by the protective layer and the second coating layer of the backside protection film.

20. The method as claimed in claim 16, wherein forming each semiconductor package includes encapsulating at least three sides of each semiconductor chip by the protective layer and the backside protection film, the backside protection film including two coating layers cured into a single layer.
